(19) United States
(12) Patent Application Publication
(10) Pub. No.: US 2025/0332766 A1
(43) Pub. Date: Oct. 30, 2025

(54) MOLDING DIE, RESIN MOLDING APPARATUS, AND METHOD FOR PRODUCING RESIN MOLDED PRODUCT

(71) Applicant: TOWA CORPORATION, Kyoto (JP)

(72) Inventors: Seitaro OKAJIMA, Kyoto (JP); Akito OBA, Kyoto (JP)

(73) Assignee: TOWA CORPORATION, Kyoto (JP)

(21) Appl. No.: 18/866,993

(22) PCT Filed: May 16, 2023
(86) PCT No.: PCT/JP2023/018236

§ 371 Date: Nov. 18, 2024

(30) Foreign Application Priority Data
Sep. 27, 2022 (JP) 2022-153297

(51) Int. Cl. B29C 43/36; B29C 33/68; B29C 43/18; B29K 21/00; B29L 9/00; B29L 31/34

(52) U.S. Cl. CPC B29C 43/36; B29C 33/68; B29C 43/18; B29C 2043/181; B29C 2043/3605; B29K 2021/006; B29L 2009/005; B29L 2031/3481

(57) ABSTRACT

Provided is a molding die capable of preventing a substrate from falling from an upper die even when warpage of the substrate occurs. This molding die for molding resin through compression molding includes: an upper die in which multiple substrate suction holes for suctioning a substrate and multiple film suction holes for suctioning a release film are formed so as to open on a lower surface of the upper die; a lower die disposed below the upper die in the vertical direction; and multiple pressing members provided to the upper die such that the pressing members can move up and down, and a lower end part thereof can protrude downwardly from the lower surface of the upper die.

### TECHNICAL FIELD

The present invention relates to the technology of a molding die, a resin molding apparatus, and a method for producing a resin molded product.

### DESCRIPTION OF RELATED ART

Patent Literature 1 discloses a resin sealing apparatus in which an upper die release film is disposed on an upper die, and a work is disposed on the upper die release film. Specifically, multiple work suction holes are formed in the upper die release film, and a suction device such as a pump can hold the work on the upper die by suctioning the work via the work suction holes.

### RELATED ART

### Patent Literature

Patent Literature 1: Japanese Patent Application Laid-Open No. 2013-153146

### SUMMARY

### Technical Problem

However, in the technology described in Patent Literature 1, when the mold is opened after resin sealing, warpage may occur in the work due to the difference in thermal shrinkage rates between the work and the resin. If warpage occurs in the work and the work separates from the work suction holes of the upper die release film, the work suction holes are opened, and the suction device ends up suctioning the surrounding air via the work suction holes. As a result, the suction force on the work decreases, and the work may fall from the upper die.

Moreover, although the resin sealing apparatus in Patent Literature 1 uses an upper die release film, even in a resin sealing apparatus that does not use an upper die release film, the work may fall if warpage occurs in the work, similar to the example described in Patent Literature 1.

The present invention has been made in view of the above-described situation, and the problem to be solved is to provide a molding die, a resin molding apparatus, and a method for producing a resin molded product that are capable of preventing a substrate from falling from the upper die even in the case where warpage occurs in the substrate.

### Solution to the Problem

The problem to be solved by the present invention is as described above, and to solve the problem, the molding die according to the present invention is a molding die for performing resin molding by compression molding, and includes: an upper die formed with multiple substrate suction holes for suctioning a substrate and multiple film suction holes for suctioning a release film, both opening on a lower surface; a lower die disposed below the upper die in a vertical direction; and multiple pressing members provided on the upper die so as to be movable up and down, with lower end parts thereof capable of protruding downward from the lower surface of the upper die.

Moreover, the resin molding apparatus according to the present invention includes the aforementioned molding die and a mold clamping mechanism that performs mold clamping of the aforementioned molding die.

Furthermore, the method for producing a resin molded product according to the present invention is a method for producing a resin molded product using the aforementioned resin molding apparatus, and includes: a film disposition process in which the aforementioned release film is disposed in the aforementioned molding die; a loading process in which a resin material is loaded into the aforementioned molding die; a mold clamping process in which mold clamping of the aforementioned molding die is performed; a resin molding process in which the aforementioned resin material is cured to perform resin molding; and a mold opening process in which mold opening of the aforementioned molding die is performed.

### Effects

According to the present invention, the substrate can be prevented from falling from the upper die even in the case where warpage occurs in the substrate.

### BRIEF DESCRIPTION OF THE DRAWINGS

FIG. 1 is a front cross-sectional view showing the configuration of a resin molding apparatus according to a first embodiment.

FIG. 2(a) is a bottom view of the suction member. (b) is a bottom view of the release film provided on the upper die.

FIG. 3 is a flowchart showing a method for producing a resin molded product.

FIG. 4 is a front cross-sectional view showing the resin molding apparatus in a state in which the substrate is suctioned to the upper die.

FIG. 5 is a front cross-sectional view showing the resin molding apparatus during execution of the resin molding process.

FIG. 6 is a front cross-sectional view of the resin molding apparatus showing a state in which the substrate has deformed after mold opening.

FIG. 7 is a front cross-sectional view showing the configuration of the resin molding apparatus in the case of sandwiching the substrate between the upper die and the lower die.

FIG. 8 is a front cross-sectional view showing the configuration of the resin molding apparatus according to a second embodiment.

FIG. 9 is a front cross-sectional view of the resin molding apparatus showing a state in which the substrate has deformed after mold opening.

FIG. 10 is a front cross-sectional view showing the configuration of the resin molding apparatus in the case of sandwiching the substrate between the upper die and the lower die.

### DESCRIPTION OF EMBODIMENTS

### Resin Molding Apparatus 100 (First Embodiment)

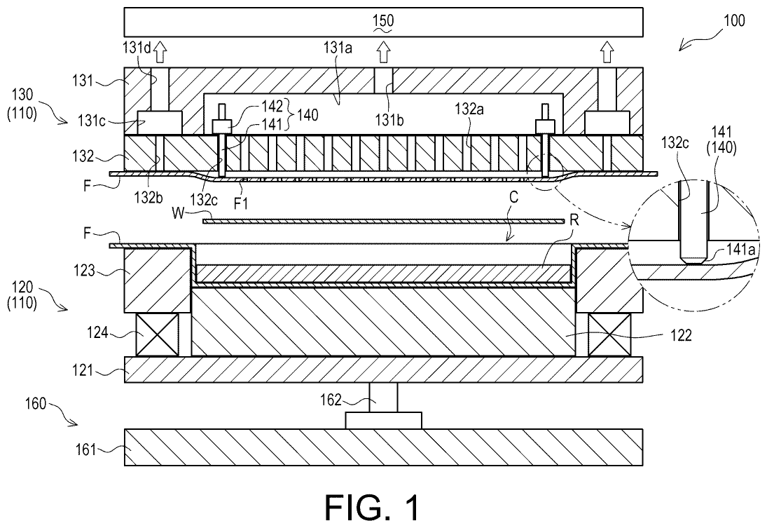

First, a resin molding apparatus 100 according to a first embodiment will be described using FIG. 1.

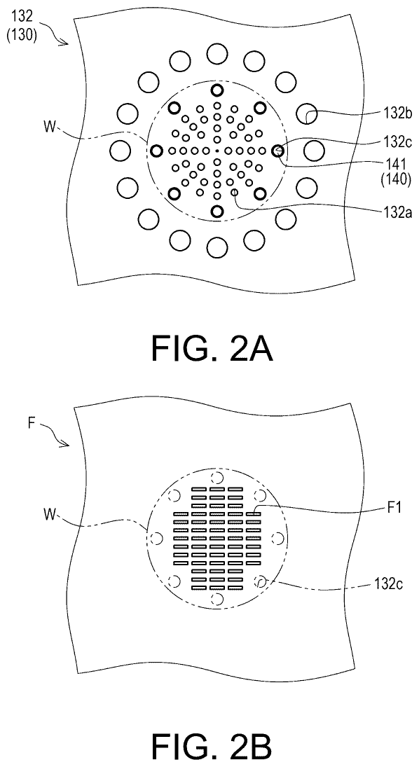

The resin molding apparatus 100 shown in FIG. 1 is an apparatus capable of resin molding by a compression molding method. The resin molding apparatus 100 according to the embodiment can perform resin sealing of electronic elements such as semiconductor chips mounted on a substrate W, which is an object to be molded, and produce a resin molded product. As the substrate W, a semiconductor substrate such as a silicon wafer, a metal substrate, a glass substrate, a ceramic substrate, or a resin substrate can be used. Furthermore, the substrate W may or may not have wiring applied. In each of embodiments described below, the substrate W of a circular shape or a rectangular shape is used. In FIG. 2, an example using the substrate W of a circular shape is shown as an example. The resin molding apparatus 100 primarily includes a molding die 110, a pump 150, and a mold clamping mechanism 160.

The molding die 110 forms a cavity C into which a resin material R having thermosetting properties is injected. The molding die 110 primarily includes a lower die 120, an upper die 130, and a pressing member 140.

The lower die 120 primarily includes a lower die base member 121, a bottom surface member 122, a side surface member 123, and an elastic member 124.

The lower die base member 121 supports the bottom surface member 122 and the side surface member 123, which will be described later.

The bottom surface member 122 forms the bottom surface of the cavity C. The bottom surface member 122 is formed, for example, in a circular shape in plan view or a rectangular shape in plan view. The bottom surface member 122 is formed to have an appropriate up-down width. The bottom surface member 122 is disposed in a state in which the bottom surface member 122 is loaded on the upper surface of the lower die base member 121.

The side surface member 123 surrounds the bottom surface member 122 from the side. The side surface member 123 is formed to have an appropriate up-down width. A hollow part that penetrates up and down through the center of the side surface member 123 is formed in the side surface member 123. The hollow part of the side surface member 123 is formed in a shape that approximately matches the outer shape of the bottom surface member 122 in plan view.

In this way, the side surface member 123 is formed in a frame shape that is circular in plan view or rectangular in plan view. The bottom surface member 122 is disposed in the hollow part of the side surface member 123. The side surface member 123 is disposed in a state in which the side surface member 123 is loaded on the upper surface of the lower die base member 121 via the elastic member 124, which will be described later. The upper surface of the side surface member 123 is positioned above the upper surface of the bottom surface member 122. The cavity C for performing resin molding is defined by the side surface member 123 and the bottom surface member 122, as well as the upper die 130, which will be described later.

The elastic member 124 is disposed between the side surface member 123 and the lower die base member 121. The elastic member 124 is formed, for example, by a compression coil spring that is capable of extending and contracting up and down.

In addition, suction holes (not shown) for suctioning and holding a release film F are appropriately formed on the upper surface of the lower die 120 (the bottom surface member 122 and the side surface member 123). By applying negative pressure to the suction holes using a pump or the like (not shown), the release film F can be suctioned and held.

The upper die 130 is disposed above the lower die 120 in the vertical direction. The upper die 130 primarily includes an upper die base member 131 and a suction member 132, among others.

The upper die base member 131 supports the suction member 132, which will be described later. The upper die base member 131 is formed, for example, in a circular shape in plan view or a rectangular shape in plan view. The upper die base member 131 is formed to have an appropriate up-down width. The upper die base member 131 includes a central concave part 131a, a central through-hole 131b, an annular concave part 131c, and an outer through-hole 131d.

The central concave part 131a is a concave portion formed in the central part of the lower surface of the upper die base member 131. The central concave part 131a is formed, for example, in a circular shape in bottom view or a rectangular shape in bottom view. The central concave part 131a is formed to extend over the range in which substrate suction holes 132a and the through-hole 132c of the suction member 132, which will be described later, are formed.

The central through-hole 131b is a hole formed to penetrate the upper die 130 up and down in the vicinity of the center of the central concave part 131a.

The annular concave part 131c is a concave portion formed in an annular shape surrounding the central concave part 131a from the outside on the lower surface of the upper die base member 131. The annular concave part 131c is formed, for example, in an annular shape in bottom view. The annular concave part 131c is formed on the lower surface of the upper die base member 131 with an appropriate gap between the annular concave part 131c and the central concave part 131a so as not to connect with the central concave part 131a.

The outer through-hole 131d is a hole formed to penetrate the upper die 130 up and down in the annular concave part 131c. Multiple outer through-holes 131d are formed along the annular concave part 131c.

The suction member 132 is for suctioning and holding the release film F and the substrate W. The suction member 132 is formed, for example, in a circular shape in plan view or a rectangular shape in plan view (the same shape as the upper die base member 131). The suction member 132 is formed to have an appropriate up-down width. The suction member 132 is fixed to the lower surface of the upper die base member 131. The suction member 132 includes a substrate suction hole 132a, a film suction hole 132b, and a through-hole 132c.

The substrate suction hole 132a shown in FIG. 1 and FIG. 2(a) is for suctioning the substrate W. The substrate suction hole 132a is formed to penetrate the suction member 132 up and down. As shown in FIG. 2(a), multiple substrate suction holes 132a are formed in the range facing the substrate W to be suctioned. In the example shown in FIG. 2(a), since the substrate W of a circular shape is used, the substrate suction holes 132a are formed over a circular range. The substrate suction holes 132a are formed to be continuous with the central concave part 131a of the upper die base member 131.

The film suction hole 132b shown in FIG. 1 and FIG. 2(a) is for suctioning the release film F. The film suction hole 132b is formed to penetrate the suction member 132 up and down. Multiple film suction holes 132b are formed to be arranged in an annular shape along the annular concave part 131c of the upper die base member 131.

The through-hole 132c is for disposing the pressing member 140 to be described later. The through-hole 132c is formed to penetrate the suction member 132 up and down. As shown in FIG. 2(a), the through-hole 132c is formed to face the outer peripheral portion of the substrate W to be suctioned. Multiple through-holes 132c are formed to be arranged in an annular shape along the circumferential direction of the substrate W.

As shown in FIG. 2(a), the substrate suction holes 132a and the through-holes 132c are formed inside the area surrounded by multiple film suction holes 132b. Specifically, the substrate suction holes 132a and the through-holes 132c are formed inside the area (an approximately circular area in bottom view) defined by connecting adjacent film suction holes 132b.

In addition, the substrate suction holes 132a are formed inside the area surrounded by multiple through-holes 132c. Specifically, the substrate suction holes 132a are formed inside the area (an approximately circular area in bottom view) defined by connecting adjacent through-holes 132c.

It should be noted that in FIG. 2(a), to make it easier to distinguish between the substrate suction holes 132a, the film suction holes 132b, and the through-holes 132c from each other, the sizes of the substrate suction holes 132a and others are shown to be extremely different. However, the sizes of the substrate suction holes 132a and others are not limited to the illustrated example and can be set arbitrarily.

The pressing member 140 shown in FIG. 1 is for pressing the release film F suctioned to the upper die 130 downward. The pressing member 140 primarily includes a pressing part 141 and a restricting part 142.

The pressing part 141 is a portion formed in an elongated columnar (rod-like) shape up and down. The cross-section of the pressing part 141 is formed in a circular shape, similar to the through-hole 132c of the suction member 132. The length of the pressing part 141 is formed to be longer than the up-down width of the suction member 132. The pressing part 141 is inserted into the through-hole 132c. The pressing part 141 can move freely up and down in relation to the through-hole 132c.

A tapered part 141a, which gradually decreases in diameter towards the downward direction, is formed at the lower end part of the pressing part 141. By forming the tapered part 141a, the corner of the lower end part of the pressing part 141 can be made obtuse, thereby preventing damage to the release film F. In addition, damage to the release film F can also be prevented by making the corner part of the lower end of the pressing part 141 curved (R-shaped).

The restricting part 142 is a portion that restricts the downward movement of the pressing part 141. The restricting part 142 is formed at the middle part of the pressing part 141 in the up-down direction. The cross-section of the restricting part 142 is formed in a shape that cannot pass through the through-hole 132c of the suction member 132. In the embodiment, the cross-sectional area of the restricting part 142 is formed to be larger than the cross-sectional areas of the pressing part 141 and the through-hole 132c. For example, the cross-section of the restricting part 142 is formed in a circular shape that is one size larger than the cross-section of the pressing part 141. The restricting part 142 may be formed by a separate member from the pressing part 141 or may be formed by a member integral with the pressing part 141.

The pressing part 141 (the portion below the restricting part 142) of the pressing member 140 is inserted into the through-hole 132c from above the suction member 132. When the pressing part 141 of the pressing member 140 is inserted into the through-hole 132c, the pressing member 140 moves downward due to its own weight. When the lower end part of the pressing part 141 protrudes below the lower surface of the suction member 132 by a predetermined amount, the restricting part 142 comes into contact with the upper surface of the suction member 132, thereby restricting the downward movement of the pressing member 140. The upper part of the pressing member 140 is accommodated inside the central concave part 131a of the upper die base member 131.

The pump 150 is for suctioning air. The pump 150 is connected to the central through-hole 131b and the outer through-hole 131d of the upper die base member 131 via appropriate hoses or the like. When the pump 150 operates, the film suction hole 132b of the suction member 132 is vacuum-drawn and becomes negative pressure via the outer through-hole 131d and the annular concave part 131c. As a result, the release film F can be suctioned and held to the lower surface of the suction member 132.

In addition, when the pump 150 operates, the substrate suction hole 132a of the suction member 132 is vacuum-drawn and becomes negative pressure via the central through-hole 131b and the central concave part 131a. In this way, by utilizing the central concave part 131a, negative pressure can be applied collectively to multiple substrate suction holes 132a. Here, as shown in FIG. 2(b), numerous minute through-holes F1 are formed in the release film F that is suctioned to the suction member 132 (upper die 130). The through-holes F1 are formed to be positioned inside the area surrounded by the through-holes 132c of the suction member 132 when the release film F is suctioned to the suction member 132. The through-hole F1 can be formed using, for example, a laser or an appropriate tool (a needle, a cutter, etc.). When the substrate suction hole 132a of the suction member 132 becomes negative pressure, the through-holes F1 of the release film F held by the suction member 132 also become negative pressure, allowing the substrate W to be suctioned and held to the bottom surface of the release film F.

In the embodiment, while an example is shown in which one pump 150 creates negative pressure in both the central through-hole 131b and the outer through-hole 131d, negative pressure may be created in the central through-hole 131b and the outer through-hole 131d using separate pumps 150, for example.

The mold clamping mechanism 160 is for performing mold clamping and mold opening, and the like by raising and lowering the lower die 120. The mold clamping mechanism 160 primarily includes a base 161 and a drive mechanism 162, etc.

The base 161 is for supporting the molding die 110, etc. The base 161 is disposed below the molding die 110 (lower die 120).

The drive mechanism 162 is for raising and lowering the lower die 120. For the drive mechanism 162, a ball screw mechanism, hydraulic cylinder, toggle mechanism, etc. can be used. The drive mechanism 162 is disposed between the base 161 and the lower die base member 121.

The operations of each of parts of the aforementioned resin molding apparatus 100 are appropriately controlled by a control device that is not shown in the figure.

### Method for Producing Resin Molded Product

Next, an example of a method for producing a resin molded product using the resin molding apparatus 100 will be described.

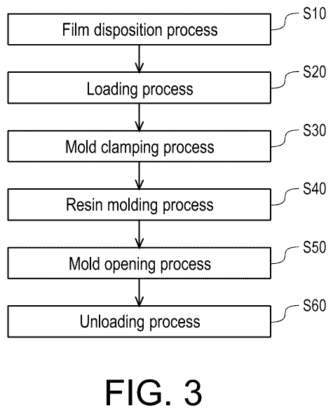

As shown in FIG. 3, the method for producing a resin molded product according to the embodiment primarily includes a film disposition process S10, a loading process S20, a mold clamping process S30, a resin molding process S40, a mold opening process S50, and an unloading process S60. The aforementioned will be described in order below.

The film disposition process S10 is a process of disposing the release film F (refer to FIG. 1) on the lower die 120 and the upper die 130.

Specifically, in the film disposition process S10, two release films F are loaded into the molding die 110 by a predetermined transport device. The two release films F are held by being suctioned onto the upper surface of the lower die 120 and the lower surface of the upper die 130, respectively.

At this time, one of the release films F is suctioned to the lower die 120 and disposed to follow the shape of the upper surface of the lower die 120. The other release film F is suctioned to the film suction holes 132b of the upper die 130, which have become negatively pressurized due to the operation of the pump 150. The release film F suctioned to the upper die 130 is slightly pushed downward by the pressing member 140 protruding from the suction member 132, so the release film F suctioned to the upper die 130 is held in a state in which a part thereof is floating from the lower surface of the upper die 130.

By providing the release film F on the molding die 110, adhesion of the resin material R to the surface of the molding die 110 can be prevented. In addition, in the case where foreign matter is adhered to the surface of the upper die 130, since the release film F is disposed between the upper die 130 and the substrate W, direct contact of the foreign matter with the substrate W can be prevented, thereby suppressing the occurrence of damage to the substrate W. Furthermore, in the case where foreign matter adheres to the surface of the molding die 110 (release film F), the foreign matter can be easily removed by replacing the release film F.

It should be noted that the release film F may be disposed on either the lower die 120 or the upper die 130 first, or the release film F may be disposed on the lower die 120 and the upper die 130 simultaneously.

After the release film F is suctioned to the lower die 120 and the upper die 130, the process transitions from the film disposition process S10 to the loading process S20.

The loading process S20 is a process of loading the resin material R and the substrate W into the molding die 110.

Specifically, in the loading process S20, the resin material R is loaded into the molding die 110 by a predetermined transport device. The resin material R is accommodated inside the lower die 120 (inside the side surface member 123). It should be noted that resin in various states can be used as the resin material R, such as solid powdered resin (including granular resin) or liquid resin in a liquid state.

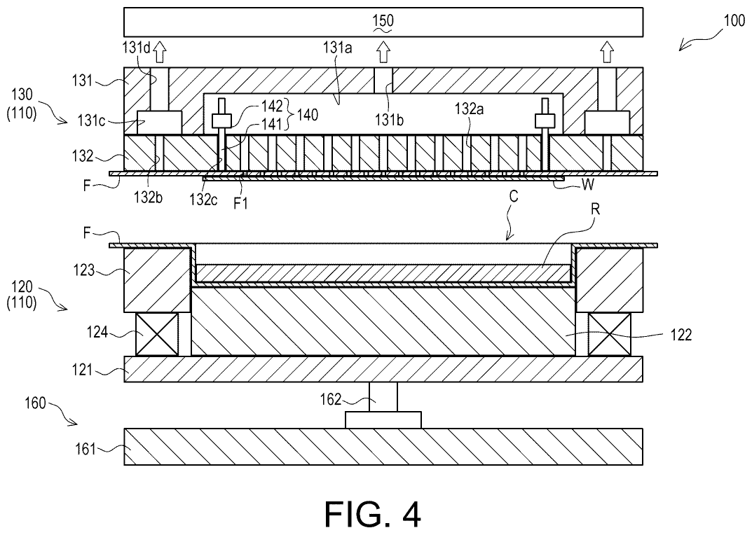

In addition, in the loading process S20, the substrate W is loaded into the molding die 110 by a predetermined transport device. As shown in FIG. 4, the substrate W is suctioned to the substrate suction holes 132a of the upper die 130, which have become negatively pressurized due to the operation of the pump 150. As a result, the substrate W is held to closely adhere to the lower surface of the suction member 132 via the release film F. At this time, the pressing member 140 is pushed upward by the substrate W suctioned to the suction member 132.

It should be noted that the order in which the resin material R and the substrate W are loaded is not particularly limited, and either may be loaded into the molding die 110 first, or both may be loaded into the molding die 110 simultaneously.

After the loading of the resin material R and the substrate W is completed, the process transitions from the loading process S20 to the mold clamping process S30.

The mold clamping process S30 is a process of closing (clamping) the molding die 110 (the lower die 120 and the upper die 130).

Specifically, in the mold clamping process S30, first, the resin material R accommodated in the cavity C is melted if it is in a solid state, or viscosity of the resin material R accommodated in the cavity C is reduced if it is in a liquid state, by a heating mechanism (not shown) provided in the lower die 120. Next, the drive mechanism 162 is actuated, causing the lower die 120 to rise towards the upper die 130. When the lower die 120 rises to a predetermined position, the upper surface of the side surface member 123 comes into contact with the lower surface of the upper die 130, and the lower die 120 (the space in which the resin material R is accommodated) is sealed from above by the upper die 130.

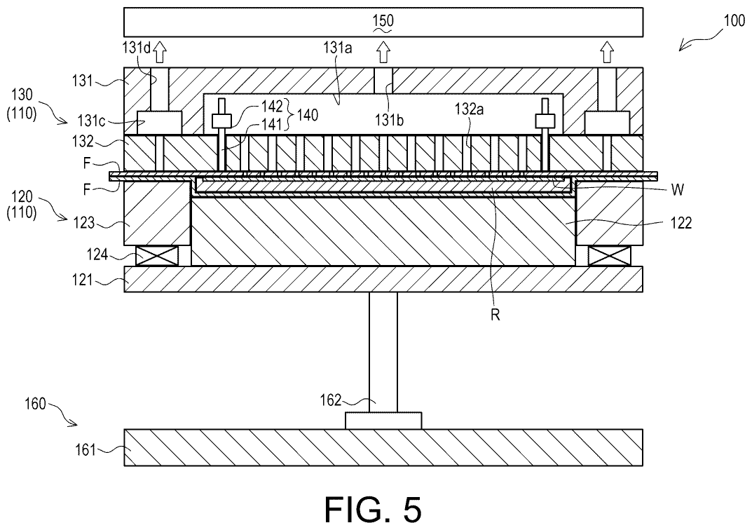

As shown in FIG. 5, the drive mechanism 162 is further actuated, causing the bottom surface member 122 of the lower die 120 to rise further towards the upper die 130. At this time, the side surface member 123 does not rise because of being in contact with the upper die 130. In other words, the bottom surface member 122 rises relatively to the side surface member 123. As the bottom surface member 122 rises, the resin material R accommodated in the lower die 120 is pressurized. The mold clamping is completed when the bottom surface member 122 has risen to a certain extent.

It should be noted that when performing mold clamping, it is preferable to suction the air inside the molding die 110 to reduce pressure. This allows for the expulsion of air and gases from the resin material R.

After the mold clamping is completed, the process transitions from the mold clamping process S30 to the resin molding process S40.

The resin molding process S40 is a process of curing the resin material R to perform resin molding.

Specifically, in the resin molding process S40, as shown in FIG. 5, the process waits for a predetermined time while the resin material R is in a pressurized state. This allows for the curing of the resin material R and performing resin molding on the substrate W. It should be noted that the figure illustrates a method of performing resin molding beyond the outer edge of the substrate W (overmold).

After the resin material R has cured, the process transitions from the resin molding process S40 to the mold opening process S50.

The mold opening process S50 is a process of opening the molding die 110 (the lower die 120 and the upper die 130).

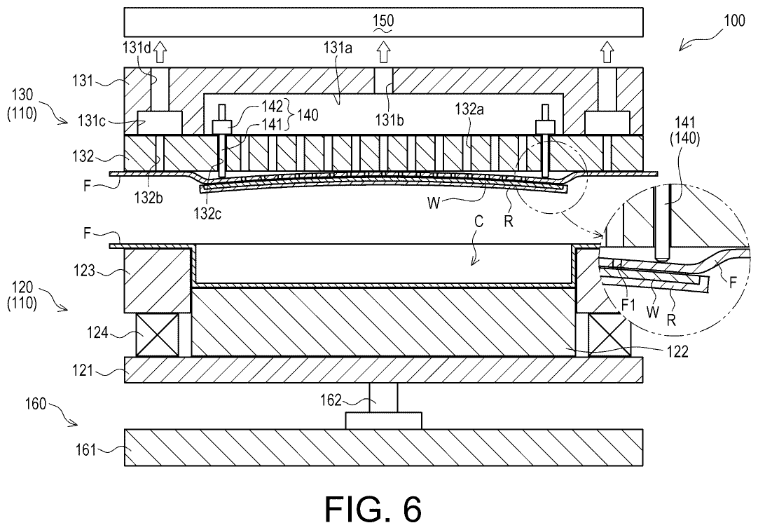

Specifically, as shown in FIG. 6, in the mold opening process S50, the drive mechanism 162 is activated, causing the lower die 120 to descend away from the upper die 130. As a result, the lower die 120 separates from the lower surface of the upper die 130.

At this point, in the resin-molded substrate W (resin molded product), deformation (warpage) may occur due to the difference in thermal shrinkage rates between the substrate W and the resin material R. For example, FIG. 6 shows an example in which the outer peripheral portion of the resin-molded substrate W is bent downward. In the case where such deformation occurs, with a conventional resin molding apparatus, the substrate W may separate from the substrate suction holes 132a (through-holes F1), resulting in a state in which the substrate suction holes 132a are open (a state in which the air inside the substrate suction holes 132a is connected to the surrounding air (external air) of the resin molding apparatus). When the substrate suction holes 132a are open, surrounding air may be drawn into the central concave part 131a via the substrate suction holes 132a, causing a decrease in the negative pressure generated by the pump 150, which may lead to the falling of the substrate W.

Therefore, in the embodiment, the falling of the substrate W is prevented by providing the pressing member 140. Specifically, as shown in FIG. 6, when the outer peripheral portion of the resin-molded substrate W is bent downward, the pressing member 140 moves downward due to its own weight accordingly. With the movement of the pressing member 140, the release film F is pushed downward to follow the substrate W. As a result, the through-holes F1 of the release film F can maintain a state of close contact with the substrate W, preventing the substrate suction holes 132a from opening, and thus maintaining the negative pressure generated by the pump 150. Consequently, the suction force on the substrate W does not decrease, and the falling of the substrate W can be prevented.

After the mold opening is completed, the process transitions from the mold opening process S50 to the unloading process S60.

The unloading process S60 is a process of unloading the resin molded product from the molding die 110. In the unloading process S60, the resin molded product is unloaded from the molding die 110 by a predetermined transport device.

In this manner, in the embodiment, even if deformation occurs in the resin-molded substrate W (resin molded product), the decrease in suction force generated by the pump 150 can be suppressed, and the falling of the substrate W can be prevented.

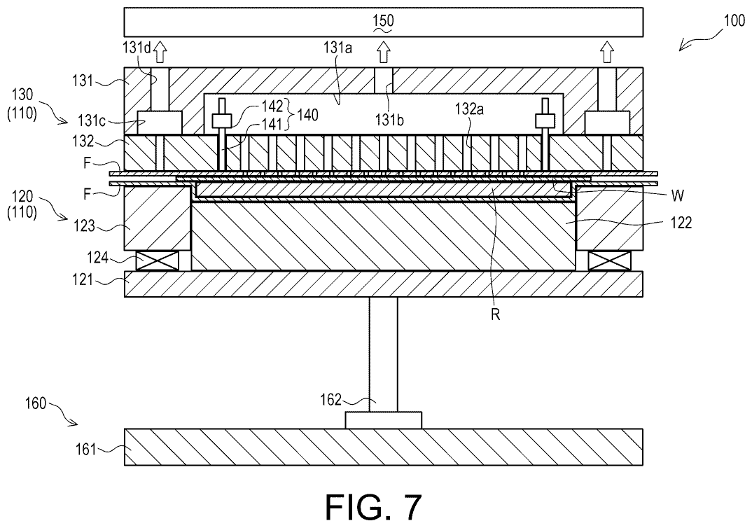

It should be noted that while FIG. 6 and others show an example of performing resin molding beyond the outer edge of the substrate W (overmold), the present invention is not limited thereto. For example, as shown in FIG. 7, when mold clamping is performed, resin molding may also be performed merely on the lower surface of the substrate W by sandwiching the outer peripheral portion of the substrate W between the side surface member 123 of the lower die 120 and the suction member 132 of the upper die 130.

### Resin Molding Apparatus 200 (Second Embodiment)

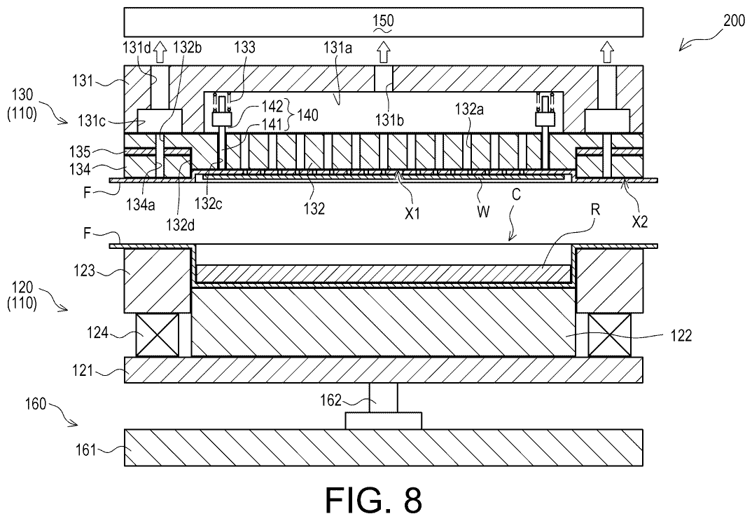

The following describes a resin molding apparatus 200 according to a second embodiment using FIGS. 8 to 10.

The point where the resin molding apparatus 200 according to the second embodiment differs from the resin molding apparatus 100 according to the first embodiment is that the upper die 130 includes an elastic member 133, an annular member 134, and a spacer 135. Therefore, in the following, we will mainly describe the difference and omit the description of the structures similar to the first embodiment.

The elastic member 133 shown in FIG. 8 is for pushing the pressing member 140 downward. In the embodiment, a compression coil spring is used as the elastic member 133. The elastic member 133 is disposed inside the central concave part 131a of the upper die base member 131. The elastic member 133 is disposed between the restricting part 142 of the pressing member 140 and the upper die base member 131, and constantly urges the pressing member 140 downward. This enhances the force with which the pressing member 140 pushes the release film F downward, allowing the release film F to follow the substrate W more reliably.

The annular member 134 is a member disposed to surround the substrate W, which is suctioned by the suction member 132, from the outside. The annular member 134 is formed in an annular shape in bottom view or a rectangular annular shape in bottom view. On the bottom surface of the suction member 132, a concave part 132d is formed in an annular shape in bottom view or a rectangular annular shape in bottom view to surround the substrate suction holes 132a and the through-holes 132c from the outside. The annular member 134 is disposed in the concave part 132d of the suction member 132.

The spacer 135 is for adjusting the up-down position of the annular member 134. The spacer 135 is formed in the same shape (annular shape or rectangular annular shape) as the annular member 134 in bottom view. The spacer 135 is formed to have a smaller up-down width compared to the annular member 134. The spacer 135 is disposed between the annular member 134 and the suction member 132.

By disposing the spacer 135 between the annular member 134 and the suction member 132, the lower surface of the annular member 134 is disposed to protrude downward beyond the lower surface of the suction member 132. The protrusion amount of the annular member 134 can be arbitrarily adjusted by changing the up-down width of the spacer 135 or by changing the number of spacers 135.

A film suction hole 134a is formed in the annular member 134 and the spacer 135 at a position corresponding to the film suction hole 132b of the suction member 132. The film suction hole 134a is formed to penetrate up and down through the annular member 134 and the spacer 135, and is connected to the film suction hole 132b.

In this manner, the lower surface of the upper die 130 is formed in a stepped shape, consisting of a first surface X1 on which the substrate suction hole 132a and the through-hole 132c are formed, and a second surface X2 formed to be disposed lower than the first surface X1 and on which the film suction hole 134a is formed.

Using the resin molding apparatus 200 configured in this manner, a resin molded product can be produced through the same processes as in the first embodiment (refer to FIG. 3).

In the film disposition process S10, the release film F provided on the upper die 130 is suctioned to the film suction hole 134a of the annular member 134.

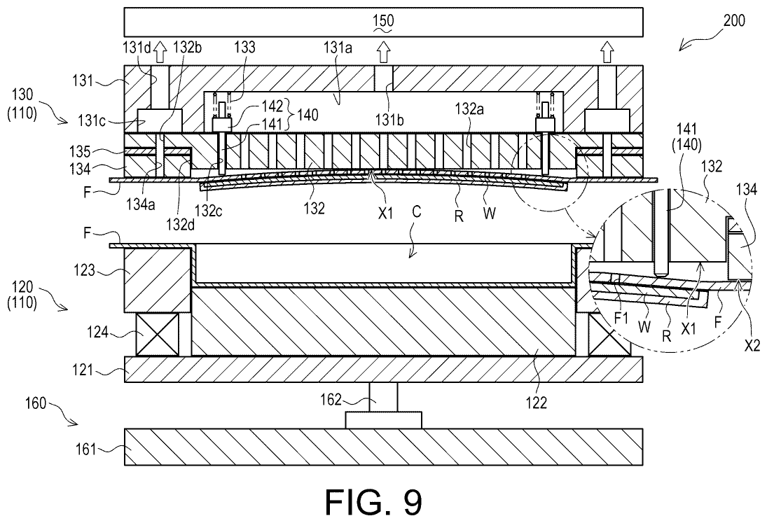

In addition, in the mold opening process S50, as shown in FIG. 9, in the case where the outer peripheral portion of the resin-molded substrate W (resin molded product) is bent downward, the pressing member 140 moves downward, similar to the first embodiment. In this case, since the pressing member 140 is pushed downward by the elastic member 133, the release film F can be made to more easily follow the substrate W.

Furthermore, since the release film F is suctioned to the annular member 134 positioned lower than the suction member 132, the pressing member 140 can push the release film F downward without difficulty. This allows the release film F to more easily follow the substrate W. In particular, in the embodiment, the vertical position (up-down position) of the second surface X2 can be adjusted by the spacer 135. Therefore, for example, by anticipating the deformation amount of the substrate W in advance and adjusting the position of the second surface X2 according to the deformation amount, the release film F can be made to more easily follow the substrate W.

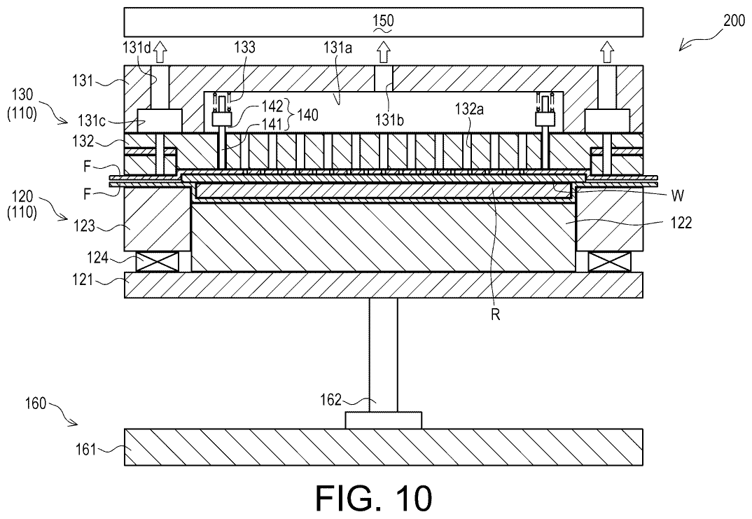

While FIGS. 8 and 9 show an example of performing resin molding beyond the outer edge of the substrate W (overmold), the present invention is not limited thereto. For example, as shown in FIG. 10, when mold clamping is performed, resin molding may also be performed merely on the lower surface of the substrate W by sandwiching the outer peripheral portion of the substrate W between the side surface member 123 of the lower die 120 and the suction member 132 of the upper die 130. In this case, the thickness of the substrate W is set to be greater than the step difference between the lower surface of the suction member 132 and the lower surface of the annular member 134.

Although the embodiments of the present invention have been described above, the present invention is not limited to the above embodiments, appropriate changes can be made within the scope of the technical idea of the invention described in the claims.

For example, the number, shape, disposition, etc. of the substrate suction holes 132a, film suction holes 132b, and pressing members 140 may be arbitrarily modified.

In addition, while FIG. 2 shows an example using the substrate W of a circular shape (refer to FIG. 2), the shape of the substrate W is not limited thereto, and the substrate W of a rectangular shape may be used, for example. Furthermore, according to the shape of the substrate W, the disposition, etc. of the substrate suction holes 132a, film suction holes 132b, and pressing members 140 may be arbitrarily modified. For example, in the case of using the substrate W of a rectangular, the pressing members 140 may be arranged in a rectangular shape along the outer peripheral portion of the substrate W. Moreover, according to the shape of the substrate W (circular, rectangular, etc.), the shape of each of parts of the resin molding apparatus 100 (such as the molding die 110) may be arbitrarily modified to a circular shape in plan view, a rectangular shape in plan view, etc.

In addition, while the above-mentioned embodiments show examples in which the outer peripheral portion of the substrate W is bent downward (refer to FIG. 6, etc.), the deformation of the substrate W is just an example, and the manner of deformation may vary according to the shape of the substrate W and the resin material R used for resin molding, and the like. Therefore, it is desirable to dispose the pressing members 140 in a way that can accommodate various manners of deformation of the substrate W. For example, it is desirable to evenly dispose the pressing members 140 in locations where the substrate W may be bent downward. By disposing the pressing members 140 in this way, no matter where the substrate W is bent downward, the pressing member 140 disposed at the location thereof can push down the release film F, allowing the release film F to follow the substrate W.

Furthermore, the present invention is not limited to the molding die 110 (resin molding apparatuses 100 and 200) that includes a release film F on the upper die 130 to prevent contamination (such as adhesion of the resin material R) of the upper die 130, but may also be applied to other molds (resin molding apparatuses). For example, in configurations in which the upper surface of the cavity C is completely covered by the substrate W, as in the resin molding apparatuses 100 and 200 shown in FIGS. 7 and 10, the resin material R does not adhere to the upper die 130. In this case, from the perspective of preventing contamination of the upper die 130, it is not needed to include the release film F on the upper die 130. However, even for molds that do not need the use of the release film F for preventing contamination, etc., the release film F and the pressing members 140, etc. may be used, as in the above-mentioned embodiments, from the perspective of preventing the substrate W from falling.

In addition, while the above-mentioned embodiments show examples in which the upper part of the pressing member 140 is disposed in the central concave part 131a of the upper die base member 131 to which negative pressure is applied by the pump 150 (refer to FIG. 1), the present invention is not limited thereto, and the disposition of the pressing member 140 may be arbitrarily modified. For example, the pressing member 140 may be disposed in a concave part provided separately from the central concave part 131a, or may be disposed so as to penetrate the upper die 130 up and down.

Furthermore, while the second embodiment shows an example of using a compression coil spring as the elastic member 133 to push down the pressing member 140 (refer to FIG. 8, etc.), the present invention is not limited thereto, and various other elastic members (for example, a leaf spring, a tension coil spring, etc.) may also be used. In addition, while the second embodiment illustrates an example of pushing the pressing member 140 downward using the elastic member 133, the configuration for pushing the pressing member 140 is not limited thereto. For example, the pressing member 140 may be pushed down using various actuators such as a motor or an air cylinder, instead of an elastic member.

Moreover, the method for producing the resin molded product shown in the above-mentioned embodiments (refer to FIG. 3) is an example, and may be modified as appropriate. For instance, while the above-mentioned embodiments show an example in which the resin material R is loaded in the loading process S20 after the release film F is disposed on the molding die 110 in the film disposition process S10, the resin material R may also be disposed on the release film F to be disposed on the lower die 120, and the release film F together with the resin material R may be disposed on the lower die 120, for example.

Furthermore, while the above-mentioned embodiments show an example of using a resin material with thermosetting properties as the resin material R, the present invention is not limited thereto, and a resin material with thermoplastic properties may be used.

### Additional Notes

The molding die 110 of the first aspect of the disclosure
is the molding die 110 for performing resin molding by compression molding, and includes
the upper die 130 formed with multiple substrate suction holes 132a for suctioning the substrate W and multiple film suction holes 132b for suctioning the release film F, opening on the lower surface thereof,
the lower die 120 disposed below the aforementioned upper die in the vertical direction, and
multiple pressing members 140 provided on the aforementioned upper die 130 to be movable up and down, such that the lower end parts thereof are capable of protruding downward from the lower surface of the aforementioned upper die 130.

According to the molding die 110 of the first aspect of the disclosure, even in the case where warpage occurs in the substrate W, the substrate W can be prevented from falling from the upper die 130. In other words, because the pressing members 140 can push down the release film F to follow the deformation of the substrate W, the substrate suction holes 132a can be prevented from being opened, and the negative pressure for suctioning the substrate W can be maintained.

In the molding die 110 of the second aspect according to the first aspect,
multiple aforementioned pressing members 140 are disposed, in a view from the vertical direction, inside an area surrounded by multiple aforementioned film suction holes 132b, and multiple aforementioned substrate suction holes 132a are formed, in a view from the vertical direction, inside an area surrounded by multiple aforementioned pressing members 140.

According to the molding die 110 of the second aspect of the disclosure, by pushing down the release film F with the pressing members 140 disposed outside the substrate suction holes 132a, the release film F can be made to more easily follow the warpage of the outer peripheral portion of the substrate W.

The molding die 110 of the third aspect according to the first or second aspect further includes
an elastic member 133 that pushes the aforementioned pressing member 140 downward.

According to the molding die 110 of the third aspect of the disclosure, the force with which the pressing member 140 pushes down the release film F may be enhanced, making it easier for the release film F to follow the warpage of the substrate W.

In the molding die 110 of the fourth aspect according to any one of the first to third aspects,
the aforementioned pressing member 140 includes a restricting part 142 that restricts downward movement.

According to the molding die 110 of the fourth aspect of the disclosure, the pressing member 140 can be prevented from falling off.

In the molding die 110 of the fifth aspect according to any one of the first to fourth aspects,
the lower end part of the aforementioned pressing member 140 is formed into a tapered shape or to have a corner part with an R shape.

According to the molding die 110 of the fifth aspect of the disclosure, damage to the release film F can be prevented.

In the molding die 110 of the sixth aspect according to any one of the first to fifth aspects,
the lower surface of the aforementioned upper die 130 includes
the first surface X1 on which the aforementioned pressing members 140 are disposed, and
the second surface X2 formed to be positioned lower than the aforementioned first surface X1, on which multiple aforementioned film suction holes 134a are formed.

According to the molding die 110 of the sixth aspect of the disclosure, the pressing member 140 can push down the release film F downward without difficulty.

In the molding die 110 of the seventh aspect according to the sixth aspect,
the aforementioned upper die 130 is configured to allow adjustment of the vertical position of the aforementioned second surface X2.

According to the molding die 110 of the seventh aspect of the disclosure, by adjusting the position of the second surface X2 to a position corresponding to the warpage of the substrate W, the release film F can be made to more easily follow the warpage of the substrate W.

The resin molding apparatus 100/200 of the eighth aspect includes
the molding die 110 according to any one of the first to seventh aspects, and
the mold clamping mechanism 160 that performs mold clamping of the aforementioned molding die 110.

According to the resin molding apparatus 100/200 of the eighth aspect of the disclosure, even in the case where warpage occurs in the substrate W, the substrate W can be prevented from falling from the upper die 130.

A method for producing a resin molded product of the ninth aspect
is a method for producing a resin molded product using the resin molding apparatus 100/200 according to the eighth aspect, and includes:
the film disposition process S10 in which the release film F is disposed in the aforementioned molding die 110;
the loading process S20 in which the resin material R is loaded into the aforementioned molding die 110;
the mold clamping process S30 in which mold clamping of the aforementioned molding die 110 is performed;
the resin molding process S40 in which the aforementioned resin material R is cured to perform resin molding; and
the mold opening process S50 in which mold opening of the aforementioned molding die 110 is performed.

### REFERENCE SIGNS LIST

100: Resin molding apparatus
110: Molding die
120: Lower die
130: Upper die
132a: Substrate suction hole
132b: Film suction hole
133: Elastic member
140: Pressing member
142: Restricting part
160: Mold clamping mechanism
200: Resin molding apparatus

1. A molding die for performing resin molding by compression molding, comprising:
an upper die, formed with a plurality of substrate suction holes for suctioning a substrate and a plurality of film suction holes for suctioning a release film, opening on a lower surface; and
a lower die, disposed below the upper die in a vertical direction; and
a plurality of pressing members, provided on the upper die so as to be movable up and down, such that lower end parts thereof are capable of protruding downward from the lower surface of the upper die.

2. The molding die according to claim 1, wherein
the plurality of pressing members are disposed, when viewed from the vertical direction, inside an area surrounded by the plurality of film suction holes, and the plurality of substrate suction holes are formed, when viewed from the vertical direction, inside an area surrounded by the plurality of pressing members.

3. The molding die according to claim 1, further comprising an elastic member, pushing the pressing member downward.

4. The molding die according to claim 1, wherein
the pressing member comprises a restricting part that restricts downward movement.

5. The molding die according to claim 1, wherein
a lower end part of the pressing member is formed into a tapered shape, or to have a corner part with an R shape.

6. The molding die according to claim 1, wherein
a lower surface of the upper die comprises
a first surface on which the pressing member is disposed, and
a second surface formed to be positioned lower than the first surface, on which the plurality of film suction holes are formed.

7. The molding die according to claim 6, wherein
the upper die is configured to allow adjustment of a vertical position of the second surface.

8. A resin molding apparatus, comprising:
the molding die according to claim 1; and
a mold clamping mechanism, performing mold clamping of the molding die.

9. A method for producing a resin molded product using the resin molding apparatus according to claim 8, comprising:
disposing the release film in the molding die;
loading a resin material into the molding die;
performing mold clamping of the molding die;
curing the resin material to perform resin molding; and
performing mold opening of the molding die.
